(19) United States
(12) Patent Application Publication
(10) Pub. No.: US 2007/0217168 A1
(43) Pub. Date: Sep. 20, 2007

(54) Method, System And Apparatus For Controlled Impedance At Transitional Plated-Through Hole Via Sites Using Barrel Inductance Minimization

(75) Inventors: Jinsaku Masuyama, Round Rock, TX (US); Rajen Murugan, Round Rock, TX (US)

Correspondence Address: BAKER BOTTS, LLP, 910 LOUISIANA, HOUSTON, TX, 77002-4995, US

(73) Assignee: DELL PRODUCTS L. P., Round Rock, TX (US)

(21) Appl. No.: 11/752,032

(22) Filed: May 22, 2007

Related U.S. Application Data
(63) Continuation of application No. 10/828,449, filed on Apr. 20, 2004.

(51) Int. Cl. H05K 7/06

(52) U.S. Cl. 361/748; 29/829

(57) ABSTRACT

A system, apparatus and method for controlled impedance at transitional via sites using barrel inductance minimization are provided. In one embodiment, one or more sidewalls of a via barrel are preferably processed such that conductive material disposed thereon is selectively removed thereby forming an inner-via trace connecting one or more conductive traces and/or pads on a first substrate layer to one or more conductive traces and/or pads on a second substrate layer. Removal of conductive material from a sidewall of the via barrel is done in a manner such that an inner-via trace traveling from a first surface to a second surface of one or more substrate layers possesses at least one electrical characteristic substantially approximating a corresponding electrical characteristic of those structures to which the inner-via trace is connected.

### TECHNICAL FIELD

The present invention relates generally to information handling systems and, more particularly, to the structure and fabrication of component substrates.

### BACKGROUND OF THE DISCLOSURE

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Achieving good signal integrity for high speed signaling requires maintaining preferred interconnect controlled impedance from the chip level to the board level. As a typical component in a substrate or printed circuit board link or channel, plated through-hole vias are usually the physical sites of impedance discontinuities or mismatches. In general, impedance discontinuities give rise to a host of signal integrity and electromagnetic interference issues included among which are reflection, noise voltage margin violations, jitter, etc.

A variety of methodologies have been designed and developed to achieve better controlled impedance at the transitional plated through-hole via level. However, many have limitations such as cost, manufacturing challenges, electrical-benefit uncertainties, etc. Among the techniques mentioned in the literature, such techniques are either sparsely used in other industries or include approaches developed with minimal or no benefit.

Among existing techniques, back drilling/counter-boring plated through-hole vias are widely practiced in data communication and telecommunication designs. One limitation of back drilling plated through-hole vias is that the process is typically restricted to printed circuit boards whose thicknesses are greater than one-hundred-twenty to one-hundred thirty (120-130) mils. This limitation is even more significant in the area of computer designs where laptops, work stations and servers typically possess printed circuit boards having a thickness no greater than eighty-five (85) mils.

### SUMMARY

In accordance with teachings of the present disclosure, an information handling system having memory, at least one processor, a printed circuit board operable to maintain the processor and the memory is provided. A plurality of vias is preferably disposed in at least one printed circuit board layer. In a preferred embodiment, the vias may be defined by a first opening on a first surface of a printed circuit board layer, a second opening at a second surface of a printed circuit board layer and at least one sidewall connecting the first and second openings and defining a void therebetween. The information handling system preferably also includes a conductive material disposed on a portion of the via sidewall, the conductive material defining at least one inner-via trace.

Further in accordance with teachings of the present disclosure, a method for manufacturing an electronic component substrate is provided. The method preferably includes defining an aperture in a first substrate layer, the aperture including a first opening at a first surface of the substrate layer, a second opening at a second surface of the substrate layer and a barrel defined by at least one sidewall creating a void and traveling between the first and second openings. The method preferably also includes creating an inner-void trace on a portion of the sidewall and traveling between the first and second surfaces. The inner-void trace preferably couples a first trace on the first surface of the substrate layer to a second trace on the second surface of the substrate layer.

Also in accordance with teachings of the present disclosure, an apparatus having at least one substrate including a first surface and a second surface, a first conductive trace disposed proximate the first surface and a second conductive trace disposed proximate the second surface is provided. The apparatus preferably also includes at least one via disposed in the substrate, the via defining an aperture in the substrate traveling from the first surface to the second surface. Further, the apparatus preferably also includes at least one conductive inner-via trace operably coupled to the via, the inner-via trace operably coupling the first conductive trace to the second conductive trace and having at least one electrical characteristic substantially approximating a corresponding electrical characteristic of a substrate surface conductive trace.

In one aspect, teachings of the present disclosure provide the technical advantage of achieving improved controlled impedance at plated through-hole vias.

In another aspect, teachings of the present disclosure provide the technical advantage of reducing radiated magnetic emission from solid cylinder vias by stripping or peeling the vias as discussed herein.

In a further aspect, teachings of the present disclosure provide the technical advantage of component substrate configuration flexibility in that teachings of the present disclosure may be used to create blind vias, buried vias, conformal vias, microvias, build-up vias, stacked vias, staggered vias, skip vias, back drilling/counter boring vias, as well as other via configurations.

In yet another aspect, teachings of the present disclosure provide the technical advantage of electronic component substrate flexibility in that teachings of the present disclosure may be employed to create chip carriers, integrated circuit packaging, PC cards, system boards, as well as other devices for maintaining and/or coupling electronic components.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 is an isometric drawing, in perspective, showing a stripped transitional via incorporating teachings of the present disclosure;

FIG. 2 is a schematic drawing illustrating one embodiment of a stripped via incorporating teachings of the present disclosure;

FIG. 3 is a schematic drawing illustrating one embodiment of a stripped via incorporating teachings of the present disclosure;

FIG. 4 is a schematic drawing illustrating one embodiment of a stripped via incorporating teachings of the present disclosure;

FIG. 5 is a cross-sectional view of a portion of a multi-layered component substrate having a varied via formed in accordance with teachings of the present disclosure;

FIG. 6 is a cross-sectional view of a multilayered component substrate having a blind via formed in accordance with teachings of the present disclosure; and

FIG. 7 is a cross-sectional view of a portion of a multilayered component substrate having a through-hole via formed in accordance with teachings of the present disclosure.

### DETAILED DESCRIPTION

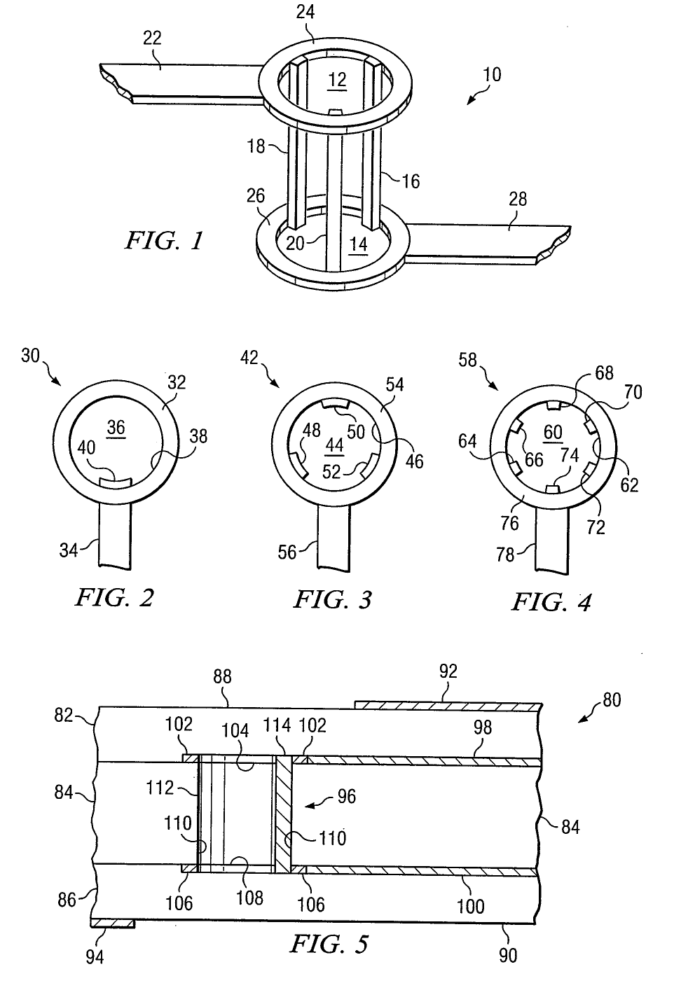

Preferred embodiments and their advantages are best understood by reference to FIGS. 1 through 7, wherein like numbers are used to indicate like and corresponding parts.

For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

Referring now to FIG. 1, an isometric view of one embodiment of a stripped transitional via is shown according to teachings of the present disclosure. As mentioned above, stripped transitional via 10 may be employed in a chip carrier, integrated circuit packaging, information handling system expansion cards, system boards, as well as in other devices operable to maintain and/or connect one or more electronic components or perform other operations. In addition, stripped transitional via 10 may be formed as a blind via, buried via, conformal via, back drilled/counterbored via, filled via, stacked via, staggered via, skip via, build-up via, as well as in one or more other via configurations.

As illustrated in FIG. 1, stripped transitional via 10 may be defined by opening 12, opening 14, and an inner-via traces 16, 18 and 20 traveling between opening 12 and opening 14. Components making stripped transitional via 10 in fact transitional include printed circuit board (PCB) or substrate layer trace 22 and conductive pad 24 effectively coupled to conductive pad 26 and second PCB or substrate layer trace 28 through inner-via traces 16, 18 and 20. Depending upon implementation, substrate layer surface trace 22 and conductive pad 24 may be disposed on an exterior or internal layer of a multilayer PCB or other component substrate. Similarly, conductive pad 26 and substrate layer surface trace 28 may be disposed on an external surface or on an internal surface of a multilayer component substrate. Additional detail concerning the positioning of traces, copper pads and inner-via traces or contacts are discussed in additional detail below.

Referring now to FIGS. 2, 3 and 4, schematic drawings depicting alternate embodiments of a stripped via are shown according to teachings of the present disclosure. Referring specifically to FIG. 2, stripped or peeled via 30 is shown coupled to conductive pad 32 and substrate layer surface trace 34. In general, stripped via 30 may be defined in part by opening 36, sidewall 38 and inner-via trace 40. Although not expressly shown in FIG. 2, sidewall 38 and inner-via trace 40 extend generally through one or more substrate layers to a second opening of stripped via 30 at a second surface of a substrate layer or multilayered substrate.

Referring specifically to FIG. 3, stripped or peeled via 42 may be generally defined by opening 44, sidewall 46 and inner-via traces 48, 50 and 52. Opening 44 of via 42 is generally surrounded by conductive pad 54 which is preferably connected to substrate layer surface trace 56. Although not expressly shown, inner wall 46 as well as inner-via traces 48, 50 and 52 generally extend to a second opening of stripped via 42 proximate a second surface of an individual layer or a multilayer substrate having one or more conductive pads and one or more substrate layer surface traces.

Referring now to FIG. 4, stripped or peeled via 58 may be generally defined by opening 60, sidewall 62 and inner-via traces 64, 66, 68, 70, 72 and 74. Proximate opening 60 is conductive pad 76. Preferably coupled to conductive pad 76 is substrate layer surface trace 78. Similar to stripped vias 30 and 42, stripped via 48 preferably includes at a second surface of a substrate layer or multilayer substrate, a second opening surrounded by a conductive pad and connected to a substrate layer surface trace. Also similar to stripped or peeled vias 30 and 42, sidewall 62 and inner-via traces 64, 66, 68, 70, 72 and 74 extend substantially to the second surface of a substrate layer or a multilayer substrate.

As illustrated in FIGS. 2, 3 and 4, a variety of configurations are possible for creating inner-via traces and, thereby, stripped or peeled vias 30, 42, and 58 as well as other embodiments of stripped vias. According to teachings of the present disclosure, the impedance of a via formed in accordance therewith may be controlled by removing conductive materials from the sidewall of an associated via through-hole such that the impedance of one or more remaining inner-via conductive traces substantially approximates an impedance of an associated conductive pad and substrate surface trace at one surface of a PCB or substrate layer or multilayer PCB or substrate and/or the conductive pad and surface trace at a second surface of a substrate or PCB multilayer substrate or PCB. As such, one goal of removing a conductive layer from a sidewall of a void defining a substrate via is to match or balance an impedance between the inner-via trace and one or more conductive surface materials or structures such that signal integrity may be maximized for signals entering into and passing out of a stripped via and/or such that power transferred into and out of a via may be optimized.

Referring now to FIG. 5, one embodiment of a buried via incorporating teachings of the present disclosure is shown. In the embodiment exemplarized in FIG. 5, multilayer PCB or substrate 80 preferably includes first layer 82, second layer 84 and third layer 86. External surfaces of multilayer substrate 80 are depicted at 88 and 90. External surfaces 88 and 90 may include one or more conductive substrate layer surface traces 92 and 94, respectively.

Buried, stripped via 96 is shown in FIG. 5 traversing the thickness of second substrate layer 84. As shown in FIG. 5, buried, stripped via 96 may be defined as a transitional via connecting substrate layer surface trace 98 to substrate layer surface trace 100. Also as illustrated in FIG. 5, substrate layer surface trace 98 is preferably coupled to conductive pad 102 disposed about opening 104 of buried, stripped via 96. Likewise, substrate layer surface trace 100 is preferably coupled to conductive pad 106 disposed about opening 108 of buried stripped via 96. As such, buried stripped via 96 may be defined at a first end by opening 104 and a second end by opening 108 with sidewall 110 traveling therebetween. In general, opening 104, opening 108 and sidewall 110 generally define a bare substrate layer barrel 112, i.e., a substrate layer barrel having little or no conductive materials on the walls thereof. As such, bore substrate layer barrel 112 may be defined as the foundation on which one or more inner-via traces may be disposed.

Illustrated in FIG. 5, is an embodiment of a buried stripped via having a single conductive inner-via trace 114. In one aspect, stripped, buried via 96, as illustrated in FIG. 5, may be a side view of the schematic shown generally in FIG. 2. As mentioned above, conductive inner-via trace 114 preferably travels along sidewall 110 of barrel 112 between openings 104 and 108. In a preferred embodiment, one or more electrical characteristics of conductive inner-via trace 14 substantially matches or balances one or more electrical characteristics of the combination of substrate layer surface trace 98 and conductive pad 102 and/or substrate layer surface trace 100 and conductive pad 106.

Buried, stripped via 96 may be formed according to a variety of methods. In one method, prior to the addition of first layer 82 or third layer 86 of multilayer substrate 80, barrel 112 may be formed in substrate layer 84 through mechanical means, laser means, or via one or more etching processes. Having traces 98 and 100 coupled to conductive pads 102 and 106, respectively, sidewall 110 of barrel 112 may then be coated with one or more conductive materials, such as screened copper, over entire sidewall 110. In the teachings of the present disclosure, a portion of the conductive material disposed on sidewall 110 may then be stripped or peeled such that an inductance of barrel 112 is minimized and an impedance match or balance between trace 98 and conductive pad 102 with trace 100 and conductive pad 106 may be achieved using desired portions of the conductive material disposed on sidewall 110 to create one or more inner-via conductive traces 114. In one embodiment, excimer lasers may be used to remove undesired portions of the conductive material disposed on sidewall 110 and thereby to create inner-via conductive trace 114 or a plurality of inner-via conductive traces. In the case of microvias, barrel 112 may be formed by mechanical means, an etching process and/or using one or more laser-based techniques.

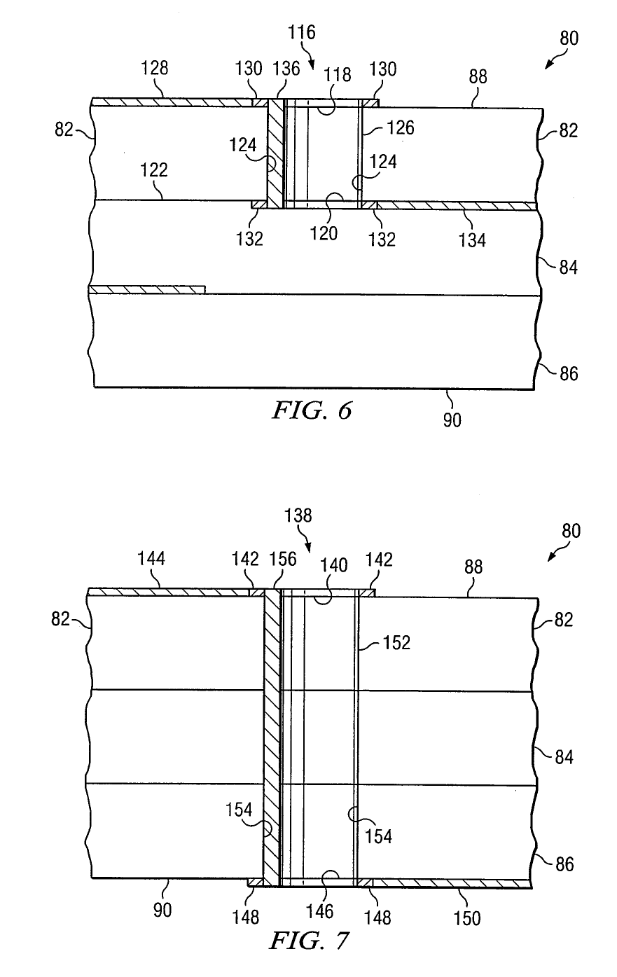

Referring now to FIG. 6, cross-sectional view of a portion of a multilayer PCB or substrate is shown according to teachings of the present disclosure. Illustrated in FIG. 6 is one embodiment of a blind, stripped via incorporating teachings of the present disclosure.

Blind, stripped via 116 may be generally defined by opening 118 at surface 88 of multilayer substrate 80 and at a second end by opening 120 at surface 122 of substrate layer 84. In addition, blind, stripped via 116 may be defined by sidewall 124 defining barrel 126 traveling between openings 118 and 120.

As illustrated in FIG. 6, blind, stripped via 116 preferably couples substrate layer surface trace 128 and associated conductive pad 130 to conductive pad 132 and substrate surface layer trace 134. Also as illustrated in FIG. 6, blind, stripped via 116 is preferably formed with a single inner-via conductive trace 136. In an alternate embodiment, blind stripped via 116 may be formed with a plurality of inner-via traces coupling substrate surface trace 128 and conductive pad 130 to conductive pad 132 and second substrate surface trace 134. In accordance with teachings of the present disclosure, inner-via trace 136 may match and/or balance one or more electrical characteristics between conductive pad 130 and substrate surface trace 128 with one or more electrical characteristics of conductive pad 132 and substrate surface trace 134.

Referring now to FIG. 7, a cross sectional view of a portion of a multilayer substrate is shown according to teachings of the present disclosure. As illustrated in FIG. 7, a stripped, plated through-hole via 138 is shown according to teachings of the present disclosure.

Stripped through-hole via 138 may be generally defined at one end by opening 140 surrounded by conductive pad 142 and coupled to substrate layer trace 144 disposed on substrate surface 88 of substrate layer 82. At a second end, stripped through-hole via 128 may be defined by opening 146 surrounded by conductive pad 148 coupled to substrate layer surface trace 150 disposed on substrate layer surface 90 of substrate layer 86. Further, stripped through-hole via 138 may be further defined by barrel 152 defined by sidewall 154 traveling between openings 140 and 146.

As illustrated in FIG. 7, stripped through-hole via 138 may be configured to traverse a multitude of layers included in a multilayer substrate 80. In the embodiment illustrated in FIG. 7, inner-via trace 156 preferably couples conductive pad 142 and substrate layer surface trace 144 on substrate surface 88 of substrate layer 82 to conductive pad 148 and substrate layer surface trace 150 disposed on substrate surface 90 of substrate layer 86. As with the examples presented previously, one or more inner-via traces may be disposed on sidewall 154 and configured to connect conductive pad 142 and substrate layer surface trace 144 to conductive pad 148 and substrate layer surface trace 150.

As mentioned above, creation of inner-via trace 156 on sidewall 154 of barrel 152 may be occasioned in a variety of manners. In one method, existing techniques for plating through-hole vias may be leveraged to achieve teachings of the present disclosure. In such standard technologies, it is customary to coat sidewall 154 of barrel 152 in its entirety with one or more conductive materials. According to teachings of the present disclosure, portions of such conductive materials are then preferably removed from sidewall 154 of barrel 152 in a stripping or peeling manner, using lasers, mechanical means, etching processes as well as other methodologies, to create one or more inner-via traces. According to teachings of the present disclosure, the creation of one or more inner-via traces having one or more electrical characteristics substantially approximating that of a conductive or copper pad and/or a conductive or copper trace at one end of the selected via with the conductive or copper pad and/or conductive or copper trace at a second end of the through-hole via is preferably obtained. For example, referring to FIG. 7, inner-via trace 156 preferably has at least an impedance value substantially equal to that of conductive pad 142 and substrate layer surface trace 144 as well as substantially equal to that of conductive pad 148 and substrate layer surface trace 150. In one aspect, goals of the teachings of the present disclosure are to increase the signal integrity of signals traveling between traces 144 and 150 as well as to make any power transfers between traces 144 and 150 more efficient.

Although the disclosed embodiments have been described in detail, it should be understood that various changes, substitutions and alterations can be made to the embodiments without departing from their spirit and scope.

What is claimed is:

1-20. (canceled)

21. An apparatus, comprising:
a printed circuit board (PCB) having at least a first PCB layer and a second PCB layer;
a via disposed in at least the first PCB layer of the PCB, wherein at least a portion of the via is defined by a first opening at a first surface of the first PCB layer, a second opening at a second surface of the first PCB layer, and a side wall connecting the first and second openings and defining a void within the first PCB layer, wherein the via terminates at one end at an interface between the first PCB layer and the second PCB layer; and
a conductive material disposed on a portion of the side wall, the conductive material defining one or more inner-via traces.

22. The apparatus of claim 21, further comprising:
the conductive material disposed on the side wall defining a plurality of inner-via traces, and
the plurality of inner-via traces arranged in a striped pattern, where the patterned stripes travel between the first opening and second opening.

23. The apparatus of claim 21, further comprising a conductive pad disposed on the first surface of the first PCB layer at the interface between the first PCB layer and the second PCB layer and coupled to the one or more inner-via traces.

24. The apparatus of claim 23, further comprising another conductive pad disposed on the second surface of the first PCB layer and coupled to the one or more inner-via traces.

25. The apparatus of claim 21, further comprising a conductive trace disposed between the first PCB layer and the second PCB layer and coupled to the one or more inner-via traces.

26. The apparatus of claim 25, further comprising another conductive trace disposed on the second surface of the first PCB layer and coupled to the one or more inner-via traces.

27. The apparatus of claim 21, wherein the one or more inner-via traces have a total impedance substantially approximating a printed circuit board surface mounted trace impedance.

28. A method, comprising:
forming a via in a first printed circuit board (PCB) layer, at least a portion of the via being defined by a first opening at a first surface of the first PCB layer, a second opening at a second surface of the first PCB layer, and a side wall connecting the first and second openings and defining a void within the first PCB layer;
forming one or more inner-void traces on a portion of the side wall, the one or more inner-void traces formed from a conductive material; and
disposing a second PCB layer adjacent the first surface of the first PCB layer such that the via terminates at one end at an interface between the first PCB layer and the adjacent second PCB layer.

29. The method of claim 28, further comprising forming multiple inner-void traces and leaving non-trace regions of the side wall substantially devoid of conductive material.

30. The method of claim 28, wherein forming one or more inner-void traces on a portion of the side wall comprises:
disposing at least one layer of conductive material on the side wall; and
removing portions of the conductive material from the side wall, leaving portions of conducting material forming the one or more inner-void traces.

31. The method of claim 28, further comprising:
disposing a first surface trace between the first PCB layer and the adjacent second PCB layer;
disposing a second surface trace coupled to the first surface trace by the one or more inner-void traces.

32. The method of claim 31, further comprising substantially balancing at least one electrical characteristic of the one or more inner-void traces to a corresponding electrical characteristic of the first and second surface traces.

33. The method of claim 32, further comprising substantially balancing an impedance value of the one or more inner-void traces with an impedance value of the first and second surface traces.

34. The method of claim 31, further comprising:
disposing the first surface trace on the first surface of the first PCB layer; and
disposing the second PCB layer adjacent the first surface of the first PCB layer such that the first surface trace is disposed between the first PCB layer and the adjacent second PCB layer.

35. The method of claim 28, further comprising:
disposing a first surface trace on the first surface of the first PCB layer, the first surface trace electrically coupled to the one or more inner-void traces;
disposing the second PCB layer adjacent the first surface of the first PCB layer such that the first surface trace is disposed between the first PCB layer and the adjacent second PCB layer;
disposing a second surface trace on the second surface of the first PCB layer, the escond surface trace electrically coupled to the one or more inner-void traces;
disposing a third PCB layer adjacent the second surface of the first PCB layer such that the second surface trace is disposed between the first PCB layer and the adjacent third PCB layer.

36. An apparatus, comprising:
a plurality of layers including a first layer having a first surface and a second surface and a second layer having a first surface disposed adjacent the first surface of the first layer;
a first conductive trace disposed between the first surface of the first layer and the first surface of the second layer;
a second conductive trace;
at least one a via disposed in the first layer, the via defining an aperture in the first layer traveling from the second surface of the first layer and terminating at an interface between the first surface of the first layer and the first surface of the second layer; and
one or more conductive inner-via traces operably coupled to the via, the one or more inner-via traces operably coupling the first conductive trace to the second conductive trace and having at least one electrical characteristic substantially approximating a corresponding electrical characteristic of a layer surface conductive trace.

37. The apparatus of claim 36, wherein the one or more inner-via traces have a total impedance measure substantially approximating an impedance measure of the first and second conductive surface traces.

38. The apparatus of claim 36, wherein the second conductive trace is disposed on an external surface of the plurality of layers.

39. The apparatus of claim 36, wherein the second conductive trace is disposed on an internal surface between two of the plurality of layers.

40. The apparatus of claim 39, wherein an impedance total for the one or more inner-via traces substantially approximates that of the first and second conductive traces.
